(19) United States
(12) Patent Application Publication
(10) Pub. No.: US 2014/0196785 A1
(43) Pub. Date: Jul. 17, 2014

(54) LIGHT CONCENTRATION MODULE

(71) Applicant: INDUSTRIAL TECHNOLOGY RESEARCH INSTITUTE, Hsinchu (TW)

(72) Inventors: Hui-Hsiung LIN, Toufen Township (TW); Wen-Hsun YANG, Taipei City (TW)

(73) Assignee: INDUSTRIAL TECHNOLOGY RESEARCH INSTITUTE, Hsinchu (TW)

(21) Appl. No.: 14/093,379

(22) Filed: Nov. 29, 2013

Related U.S. Application Data
(63) Continuation of application No. PCT/CN2013/072285, filed on Mar. 7, 2013.

(30) Foreign Application Priority Data
Jan. 11, 2013 (CN) 201310011112.2
Jan. 11, 2013 (TW) 102101199

(51) Int. Cl. H01L 31/052

(52) U.S. Cl. CPC H01L 31/0524
USPC 136/259

(57) ABSTRACT

A light concentration module includes a primary light concentration plate, a light concentration component and an electricity generation module. The primary light concentration plate includes a primary light concentration surface and a light-emitting surface. The primary light concentration surface is used for collecting light. The light-emitting surface is used for emitting light collected by the primary light concentration surface. The light concentration component includes a first surface and a second surface. The first surface collects light from the light-emitting surface. The area of the first surface is larger than the area of the second surface. The second surface is used for emitting light collected by the first surface. The electricity generation module is used for converting energy from light into electricity.

### CROSS-REFERENCE TO RELATED APPLICATIONS

This application is a Continuation of co-pending Application No. PCT/CN2013/072285, filed on Mar. 7, 2013, for which priority is claimed under 35 U.S.C. §120; and this application claims priority of Application No. 201310011112.2 filed in China on Jan. 11, 2013, and Application No. 102101199, filed in Taiwan, R.O.C. on Jan. 11, 2013 under 35 U.S.C. §119; the entire contents of which are hereby incorporated by reference.

### TECHNICAL FIELD

The disclosure relates to a light concentration module.

### BACKGROUND

As the concept of environmental consciousness has become more and more important these days, the research and development of renewable energy have played a crucial role in the related industries. Compared to the accessibility of other renewable energies, sunlight is relatively easy to access. Hence, companies in the related industries have invested a large amount of resources in the development of electricity generation from solar energy.

Nowadays, the method of electricity generation from solar energy can be classified into two types. The first type is to convert thermal energy from sunlight into electricity by photothermal conversion. The second type is to convert light energy into electricity by photoelectric conversion.

With regard to the solar cell system with multiple solar cell modules, collecting sunlight with a fixed angle is generally used to produce electricity. Nevertheless, the angle of incidence in the solar cell system varies as time passes. Also, different locations with different longitudes and latitudes have impacts on the angle of incidence in the solar cell system. The variations of the angles of incidence lead to the reduction in the absorption of sunlight, and thereby reduce the efficiency of electricity generation. Consequently, for improving the efficiency of photoelectric conversion, how to maintain the solar cell system at a fixed angle while collecting sunlight becomes an important issue to be addressed in the industry.

Furthermore, a sun tracking system for the solar cell (namely the sun tracking module combined with the solar cell module) is introduced, so as to improve the absorption efficiency of sunlight in the solar cell system. Generally speaking, the sun tracking module comprises a light sensor and a mechatronical servomechanism. The light sensor is used for detecting the change of the sun's position, in order to adjust the solar cell system to a position facing the sun by the mechatronical servomechanism. Thereby, the amount of sunlight radiation which the solar system can absorb is increased. It should be noted that the sensor is required to be assembled in an angle exactly parallel to the vertical angle of the solar cell system. Furthermore, the sensor is exposed to the environment so that it is likely to be interfered with or damaged. As a result, the sensor may be unable to detect the sun's position accurately.

### SUMMARY

In an embodiment, the disclosure provides a light concentration module comprising a primary light concentration plate, a light concentration component and an electricity generation module. The primary light concentration plate comprises a primary light concentration surface and a light-emitting surface. The primary light concentration surface is configured for collecting light. The light-emitting surface is configured for emitting light collected by the primary light concentration surface. The light concentration component comprises a first surface and a second surface. The first surface collects light from the light-emitting surface. The area of the first surface is larger than the area of the second surface. The second surface is configured for emitting light collected by the first surface. The electricity generation module is configured for converting energy from light into electricity.

### BRIEF DESCRIPTION OF THE DRAWINGS

The disclosure will become more fully understood from the detailed description given herein below for illustration only and thus does not limit the disclosure, wherein:

FIG. 1 is a perspective view of a light concentration module according to a first embodiment of the disclosure;

FIG. 2A is an enlarged side view of a primary light concentration plate in FIG. 1;

FIG. 2B is an enlarged side view of a light concentration component and an electricity generation module in FIG. 1 according to an embodiment of the disclosure;

FIG. 3 is a perspective view of a light concentration module according to a second embodiment of the disclosure;

FIG. 4A is a sectional view of a primary light concentration plate in FIG. 3 according to an embodiment of the disclosure;

FIG. 4B is a sectional view of the primary light concentration plate in FIG. 3 according to an embodiment of the disclosure;

FIG. 4C is a sectional view of the primary light concentration plate in FIG. 3 according to an embodiment of the disclosure;

FIG. 4D is a sectional view of the primary light concentration plate in FIG. 3 according to an embodiment of the disclosure;

FIG. 4E is a perspective view of a first light concentration element in FIG. 3 according to an embodiment of the disclosure;

FIG. 4F is a perspective view of a second light concentration element in FIG. 3 according to an embodiment of the disclosure;

FIG. 5A is a top view of a light concentration module according to a third embodiment of the disclosure;

FIG. 5B is a sectional view, along a I-I′ line, of a primary light concentration plate in FIG. 5A according to an embodiment of the disclosure;

FIG. 5C is a partial enlarged view of the region A in FIG. 5A;

FIG. 6 is a top view of a light concentration module according to a fourth embodiment of the disclosure;

FIG. 7A is a top view of a light concentration module according to a fifth embodiment of the disclosure;

FIG. 7B is a partial enlarged view of the region B in FIG. 7A; and

FIG. 7C a top view of a light concentration module according to a sixth embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

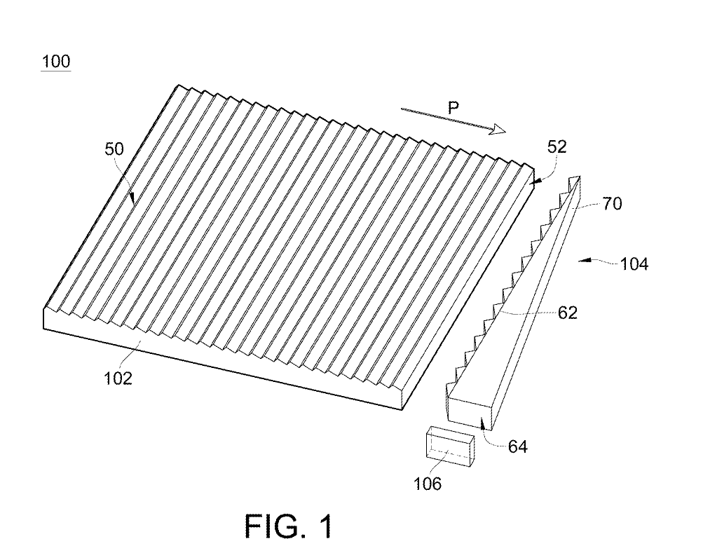

FIG. 1 is a perspective view of a light concentration module according to a first embodiment of the disclosure. As seen in FIG. 1, the light concentration module 100 of this embodiment comprises a primary light concentration plate 102, a light concentration component 104 and an electricity generation module 106.

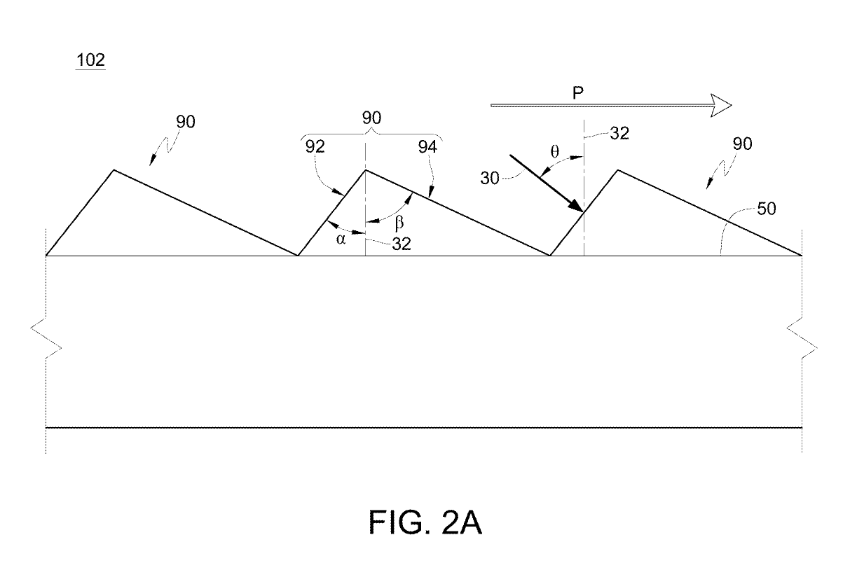

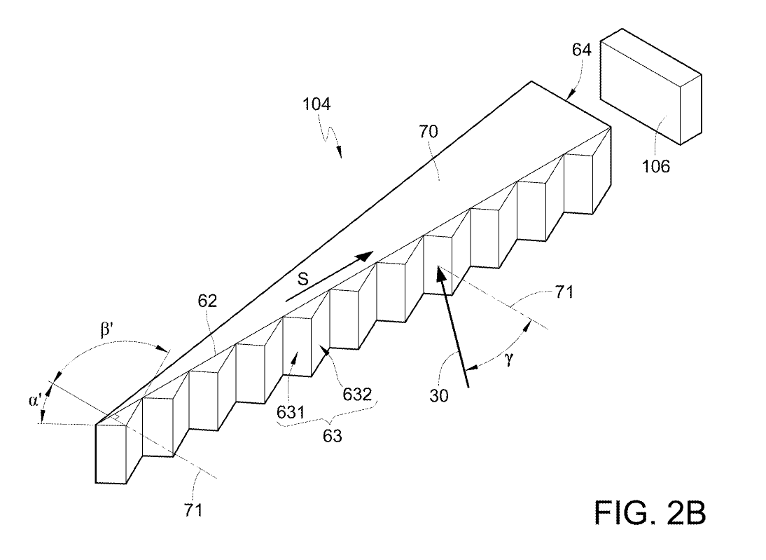

The primary light concentration plate 102 comprises a primary light concentration surface 50 and a light-emitting surface 52. The light concentration component 104 comprises a first surface 62 and a second surface 64. The area of the first surface 62 is larger than the area of the second surface 64. The primary light concentration surface 50 is configured for collecting light 30 and causes light 30 to be transmitted in the primary light concentration plate 102, and the light-emitting surface 52 is configured for emitting light 30 collected by the primary light concentration surface 50, as shown in FIG. 2A. The first surface 62 is configured for collecting light 30 from the light-emitting surface 52 and for causing light 30 to be transmitted in the light concentration component 104. The second surface 64 is configured for emitting light 30 collected from the first surface 62 to the electricity generation module 106. The electricity generation module 106 is configured for converting the energy, for example, light energy or thermal energy, from incident light 30 to electricity. Light 30 is not shown in FIG. 1 to reduce the complexity of the figure.

Referring to FIG. 2A, the primary light concentration surface 50 may comprise a plurality of first microprism structures 90. The first microprism structures 90 are arranged along a first direction P. The first direction P is from the light-emitting surface 52 to the first surface 62. Each of the first microprism structures 90 comprises a first light-facing surface 92 and a first backlight surface 94. The first direction P is perpendicular to a normal vector 32 of the primary light concentration plate 50 and the normal vector 32 is perpendicular to the primary light concentration plate 50. Each of the first microprism structures 90 satisfies the following conditions:

0°≦α≦40°; and

45°≦β<90°;

wherein α is a first included angle formed by the first light-facing surface 92 and the normal vector 32, and β is a second included angle formed by the first backlight surface 94 and the normal vector 32.

Light 30 collected by the primary light concentration plate 102 and the normal vector 32 form a third included angle θ. The third included angle θ is greater than or equal to 45 degrees and less than 90 degrees (namely 45°≦θ<90°).

The light concentration experiment of the primary light concentration plate 102 is conducted and the result thereof is illustrated below. Please refer to table 1, which shows light-emitting ratios of the first microprism structures with different first included angles α and different second included angles δ. Furthermore, the light-emitting ratio refers to the ratio of the light intensity of the light-emitting surface 52 to the light intensity of the primary light concentration plate 50.

TABLE 1

| First included angle α | Second include angle β | Light-emitting ratio |
|---|---|---|
| (degree) | (degree) | (percent) |
| 0 | 45 | 0.21 |
| 0 | 89 | 13.5 |
| 40 | 45 | 1.245 |
| 40 | 89 | 13.7 |
| 20 | 80 | 48.2 |
| 0 | 80 | 71.8 |

As shown in table 1, when 0°≦α≦40° and 45°≦β<90°, all the light-emitting ratios are greater than zero. In other words, when α and βsatisfy the above-mentioned requirements, the primary light concentration plate 102 is configured for performing the light concentration function.

Moreover, light 30 collected by the primary light concentration surface 50 and the normal vector 32 form a third included angle θ. The third included angle θ may be greater than or equal to 45 degrees and less than 90 degrees (namely 45°≦θ<90°.

Referring to FIG. 1, since the area of the first surface 62 is greater than that of the second surface 64, the concentration ratio of the light concentration module increases. Thereby, the power conversion efficiency of the electricity generation module 106 is improved. The above-mentioned concentration ratio satisfies the following conditions:

$$L = \frac{A}{C} \times \frac{cos θ}{η} \qquad ( 1 )$$

Wherein L is the concentration ratio, A is the area of the primary light concentration surface 50, C is the area of the second surface 64 (namely the light collection area of the electricity generation module 106), η is the light transmission efficiency of the light concentration module 100 (namely the ratio of the light intensity of the light 30 collected by the primary light concentration surface 50 to the light intensity of the light 30 transmitted to the electricity generation module 106).

In this embodiment, the light concentration component 104 comprises a single light concentration element 70. A light concentration element 70 has a first surface 62 and a second surface 64, but the disclosure is not limited thereto. In other embodiments, the light concentration component 104 may comprise two light concentration elements. However, as the number of the light concentration element increases, the light transmission efficiency may deteriorate because the light intensity may be lessen after multiple transmission processes.

In this embodiment, the first surface 62 may also comprise a plurality of second microprism structures 63. The second microprism structures 63 are arranged along a second direction S, as shown in FIG. 2B which is an enlarged side view of a light concentration component and an electricity generation module in FIG. 1 according to an embodiment of the disclosure. Each of the second microprism structures 63 comprises a second light-facing surface 631 and a second backlight surface 632. The second direction S is perpendicular to a vertical line 71 of the first surface 62 wherein the vertical line 71 is perpendicular to the first surface 62. Each of the second microprism structures 63 satisfies the following conditions:

0≦α′≦40°; and

45°≦β′<90°;

wherein α′ is a fourth included angle formed by the second light-facing surface 631 and the vertical line 71, and β′ is a fifth included angle formed by the second backlight surface 632 and the vertical line 71.

Light 30, collected by the light concentration element 70, and the vertical line 71 form a sixth included angle γ, the sixth included angle γ may be greater than or equal to 45 degrees and less than 90 degrees (namely 45°≦γ<90°). The design of the second microprism structures 63 is the same as the design of the first microprism structures 90 and the angle range in which the light concentration element 70 collects light 30 is the same as the angle range in which the primary light concentration plate 102 collects light 30. Hence, the light concentration element 70 is configured for performing light concentration functions.

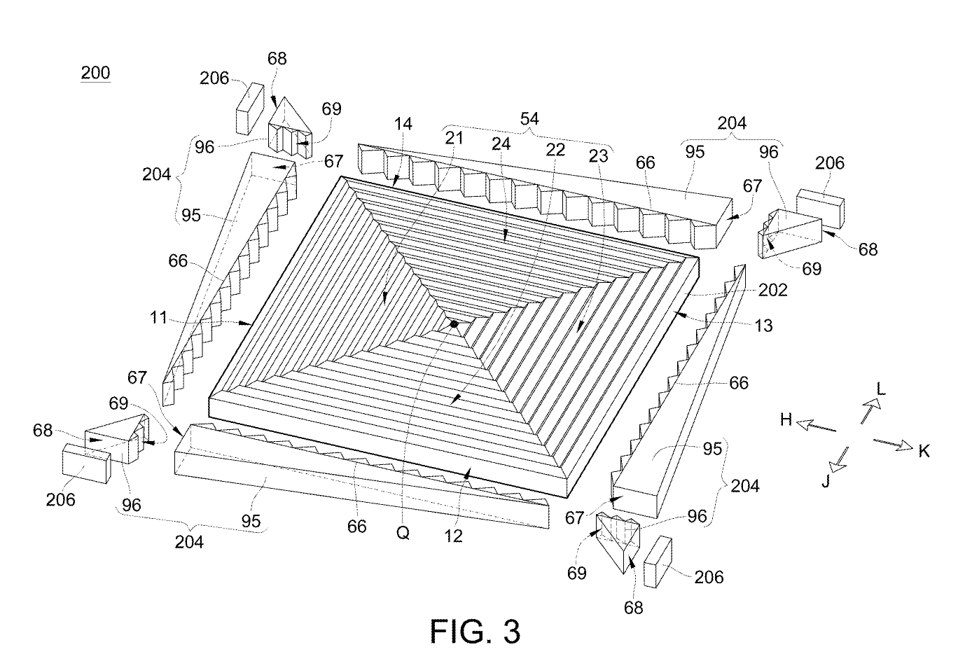

Refer to FIG. 3, which is a perspective view of a light concentration module according to a second embodiment of the disclosure. In this embodiment, the light concentration module 200 comprises a primary light concentration plate 202, four light concentration components 204 and four electricity generation modules 206. Each of the light concentration components 204 comprises a first surface 66 and a second surface 68. The area of the first surface 66 is larger than that of the second surface 68.

The primary light concentration plate 202 may comprises a primary light concentration surface 54 and a plurality of light-emitting surfaces 11, 12, 13 and 14. The primary light concentration surface 54 may comprise a plurality of subsidiary surfaces 21, 22, 23 and 24. The subsidiary surfaces 21, 22, 23 and 24 intersect at a center point Q, but the disclosure is not limited thereto.

In other embodiments, the number of the light-emitting surface, the subsidiary light concentration surface, the light concentration component and the electricity generation module can be five respectively. Moreover, in other embodiments, the primary light concentration plate can be in a pentagon shape. That is, the numbers of the light-emitting surface, the subsidiary light concentration surface, the light concentration component and the electricity generation module and the shape of the primary light concentration plate can be adjusted according to the requirements.

Specifically, the quantities of the light-emitting surface, the subsidiary light concentration surface, the light concentration component and the electricity generation module should be the same. Also, the quantities of the subsidiary light concentration surface, the light concentration component and the electricity generation module are in relation to the quantity of the light-emitting surface. In other words, the subsidiary light concentration surfaces 21, 22, 23 and 24 correspond to the light-emitting surfaces 11, 12, 13 and 14 respectively; The light-emitting surfaces 11, 12, 13 and 14 correspond to the four light concentration components 204 respectively; The four light concentration components 204 correspond to the four electricity generation module 206.

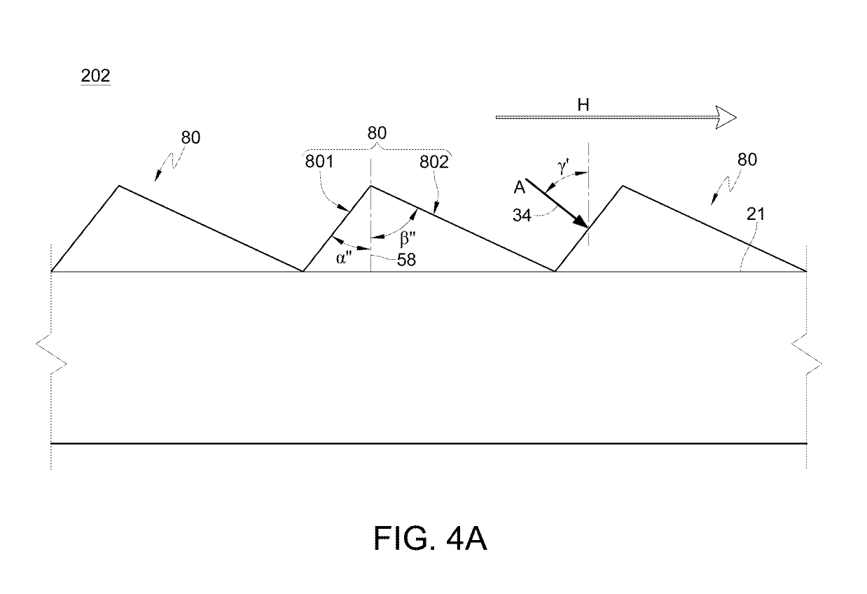

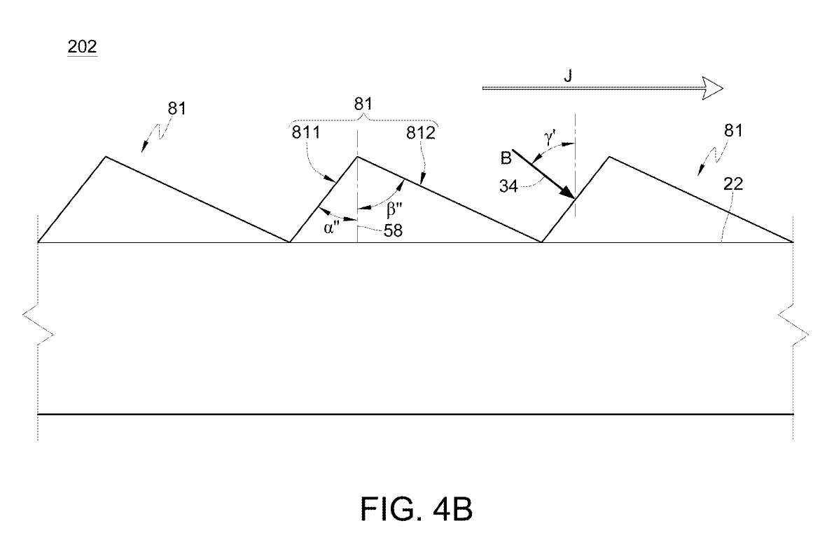

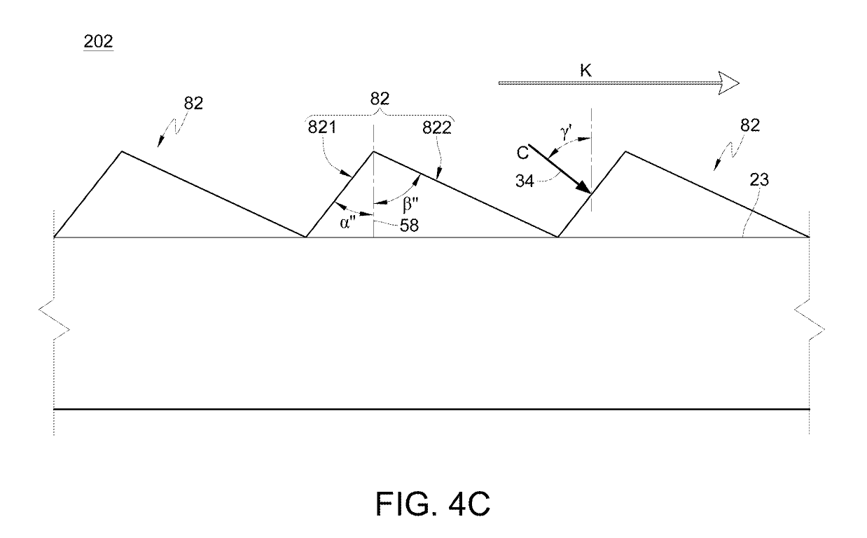

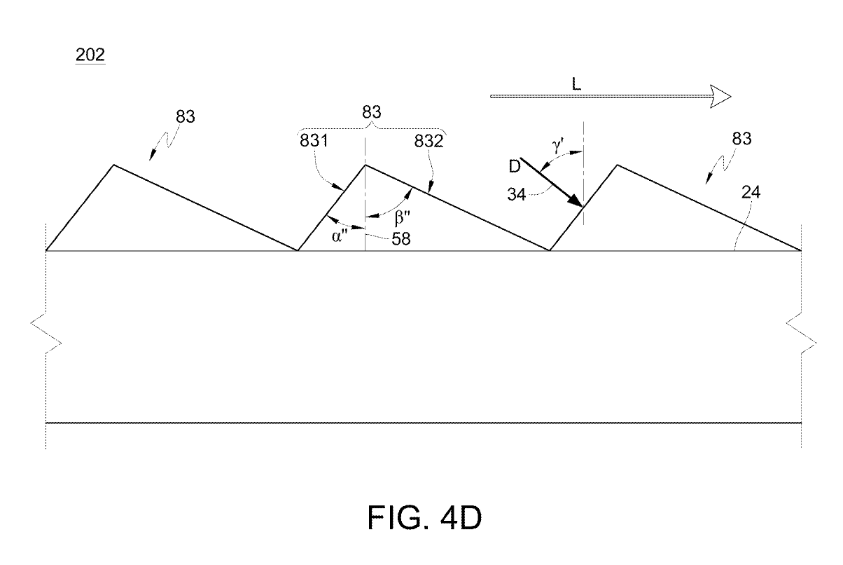

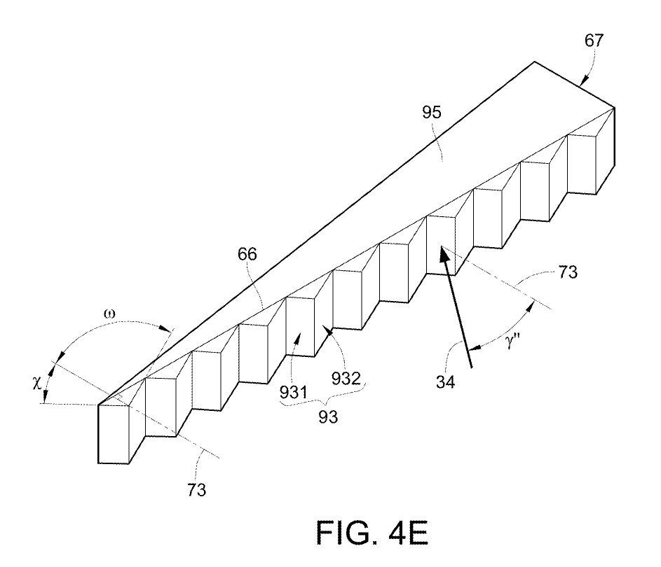

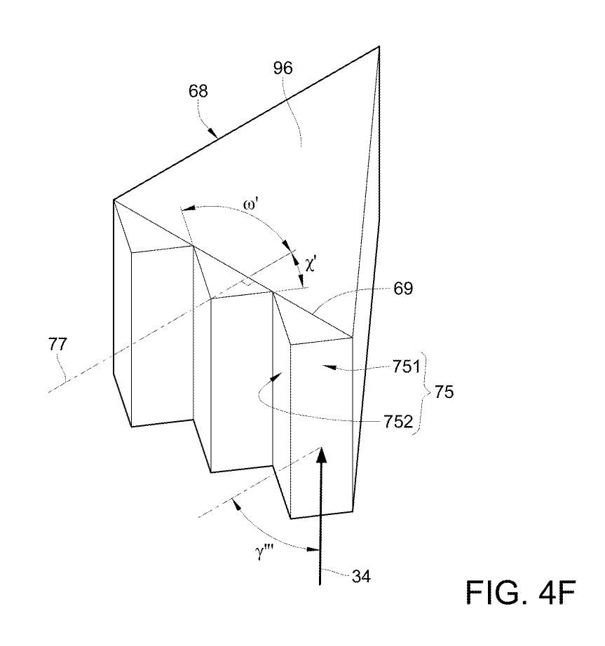

FIG. 3, FIG. 4A, FIG. 4B, FIG. 4C, and FIG. 4D are sectional views of a primary light concentration plate in FIG. 3, according to an embodiment of the disclosure. As seen in FIG. 3 to FIG. 4D, the subsidiary surfaces 21, 22, 23 and 24 are configured for collecting light 34 from a variety of incident directions, and for transmitting the light 34 to the corresponding light-emitting surfaces 11, 12, 13 and 14. The light-emitting surfaces 11, 12, 13 and 14 are configured for transmitting light 34 collected by the subsidiary surfaces 21, 22, 23 and 24 to the corresponding light concentration components 204. The light concentration components 204 are configured for transmitting light 34 collected by the first surface 66 to the corresponding electricity generation modules 206 via the second surface 68.

In this embodiment, the subsidiary light concentration surfaces 21, 22, 23 and 24 are configured for collecting light 34 from incident direction A, incident direction B, incident direction C and incident direction D respectively, but the disclosure is not limited thereto. Each of the first surfaces 66 is configured for collecting light 34 from the corresponding light-emitting surfaces 11, 12, 13 and 14. Each of the second surfaces 68 is configured for emitting light 34 from the corresponding first surfaces 66 to the corresponding electricity generation modules 206. Each of the electricity generation modules 206 is configured for converting the energy of light 34 from the corresponding second surfaces 68 to electricity. It should be noted that light 34 is omitted in order to reduce complexity in FIG. 3.

In this embodiment, light 34 collected by the subsidiary surfaces 21, 22, 23 and 24 is perpendicular to a normal vector 58 of the primary light concentration surface 54 (or the subsidiary light concentration surfaces 21, 22, 23 and 24) form a seventh included angle γ′, wherein the normal vector 58 is perpendicular to the primary light concentration surface 54 (or perpendicular to the subsidiary light concentration surfaces 21, 22, 23 and 24). The seventh included angle γ′ may be greater than or equal to 45 degrees and less than 90 degrees (namely 45°≦γ′<90°).

Furthermore, please refer to FIG. 3. In this embodiment, each of the light concentration components 204 further comprises a first light concentration element 95 and a second light concentration element 96. The first light concentration element 95 may comprise a first surface 66 and a third surface 67. The second light concentration element 96 may comprise a second surface 68 and a fourth surface 69. The area of the first surface 66 is larger than that of the third surface 67. The area of the third surface 67 is approximately the same as that of the fourth surface 69, but the disclosure is not limited thereto. The area of the fourth surface 69 is larger than that of the second surface 68.

The second light concentration element 96 is disposed next to the first light concentration element 95. Specifically, the fourth surface 69 of the second light concentration element 96 is disposed oppositely to the third surface 67 of the first light concentration element 95. Light 34, collected by the light concentration component 204, is then collected by the first surface 66 of the first light concentration element 95. Subsequently, light 34 is transmitted in the first light concentration element 95 and is emitted from the first light concentration element 95 by the third surface 67. Then, light 34 is collected by the fourth surface 69 of the second light concentration element 96, and is transmitted in the second light concentration element 96. Light 34, subsequently, is emitted form the second surface 68.

Thereby, the concentration ratio of the subsidiary surfaces 21, 22, 23 and 24 of the light concentration module 200 is increased due to the concatenation of the first light concentration element 95 and the second light concentration element 96 (that is, in the transmission path of light 34, light 34 goes through the first light concentration element 95 before going through the second light concentration element 96). As a result, the energy conversion efficiency of each of the electricity generation modules 206 is improved.

As shown in FIG. 4A, FIG. 4B, FIG. 4C and FIG. 4D, in this embodiment, the subsidiary light concentration surface 21 comprises a plurality of third microprism structures 80. The third microprism structures 80 are arranged along a corresponding direction H. The subsidiary light concentration surface 22 may comprise the third microprism structures 81. The third microprism structures 81 are arranged along a corresponding direction J. The subsidiary light concentration surface 23 comprises the third microprism structures 82. The third microprism structures 82 are arranged along a corresponding direction K. The subsidiary light concentration surface 24 comprises the third microprism structures 83. The third microprism structures 83 are arranged along a corresponding direction L. The above-mentioned corresponding directions H, J, K and L are from the center point Q to the light-emitting surfaces 11, 12, 13 and 14 respectively.

Moreover, the third microprism structures 80 may comprise a third light-facing surface 801 and a third backlight surface 802. The third microprism structures 81 may comprise a third light-facing surface 811 and a third backlight surface 812. The third microprism structures 83 may comprise a third light-facing surface 831 and a third backlight surface 832. The normal vector 58 is perpendicular to the corresponding directions H, J, K and L.

Each of the third microprism structures 80, 81, 82 and 83 satisfy the following conditions:

0≦α″≦40°; and

45°≦β″<90°;

wherein α″ is a eighth included angle formed by the third light-facing surfaces 801, 811, 821, 831 and the normal vector 58, and β″ is a ninth included angle formed by the third backlight surface 802, 812, 822, 823 and the normal vector 58.

Compared to the first embodiment in FIG. 1 and FIG. 2A, the design of the third microprism structures 80, 81, 82 and 83 are the same as the design of the first microprism structures 90. Additionally, the angle range in which the subsidiary light collection surfaces 21, 22, 23 and 24 collect light 34 is the same as the angle range in which the primary light concentration plate 102 collects light 30. Thus, the subsidiary light concentration surfaces 21, 22, 23 and 24 are configured for performing the light concentration function.

Please refer to FIG. 4E, which is a perspective view of a first light concentration element in FIG. 3 according to an embodiment of the disclosure. In this embodiment, each of the first surfaces may further comprise a plurality of fourth microprism structures 93. Each of the fourth microprism structures 93 comprises a fourth light-facing surface 931 and a fourth backlight surface 932. The fourth microprism structures 93 are arranged in a direction perpendicular to a vertical line 73 of the first surface 66, wherein the vertical line 73 is perpendicular to the first surface 66. Each of the fourth microprism structures 93 satisfies the following conditions:

0°≦χ≦40°; and

45°≦ω<90°;

wherein χ is a tenth included angle formed by the fourth light-facing surface 931 and the vertical line 73, and ω is an eleventh included angle formed by the fourth backlight surface 932 and the vertical line 73.

Light 34 collected by the first light concentration element 95 and the vertical line 73 form a twelfth included angle γ″. The twelfth included angle γ″ may be greater than or equal to 45 degrees and less than 90 degrees (namely 45°≦γ″<90°).

Moreover, please refer to FIG. 4F, which is a perspective view of a second light concentration element in FIG. 3 according to an embodiment of the disclosure. Each of the fourth surfaces 69 may comprise a plurality of fifth microprism structures 75. Each of the fifth microprism structures 75 comprises a fifth light-facing surface 751 and a fifth backlight surface 752. The fifth microprism structures 75 are arranged along a direction perpendicular to a vertical line 77 of the fourth surface 69, wherein the vertical line 77 is perpendicular to the fourth surface 69. Each of the fifth microprism structures 75 satisfies the following conditions:

0°χ′≦40°; and

45°≦ω′<90°;

wherein χ′ is a thirteenth included angle formed by the fifth light-facing surface 751 and the vertical line 77, and ω′ is a fourteenth included angle formed by the fifth backlight surface 752 and the vertical line 77. Light 34 collected by the first light concentration element 96 and the vertical line 77 form a fourteenth included angle γ′″. The fourteenth included angle γ′″ may be greater than or equal to 45 degrees and less than 90 degrees (namely 45°≦γ′″<90°).

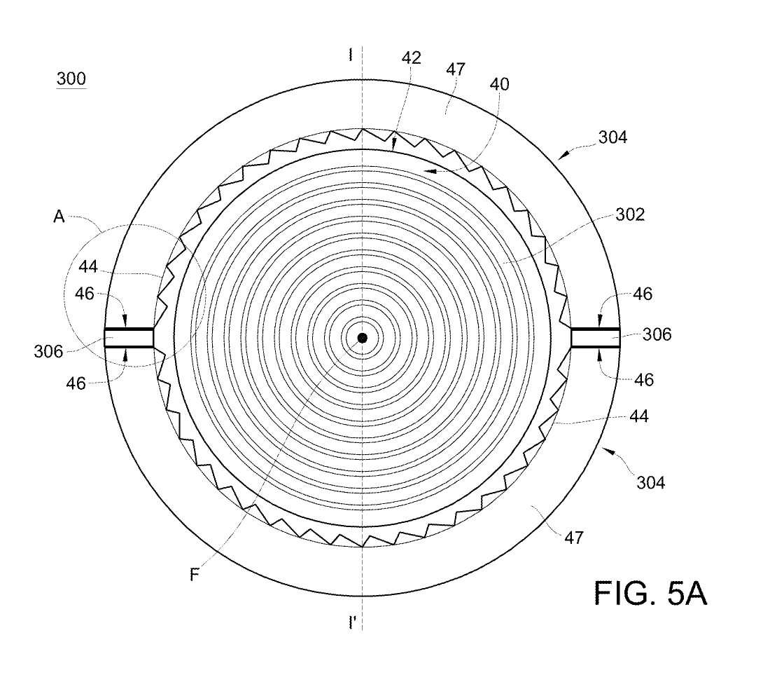

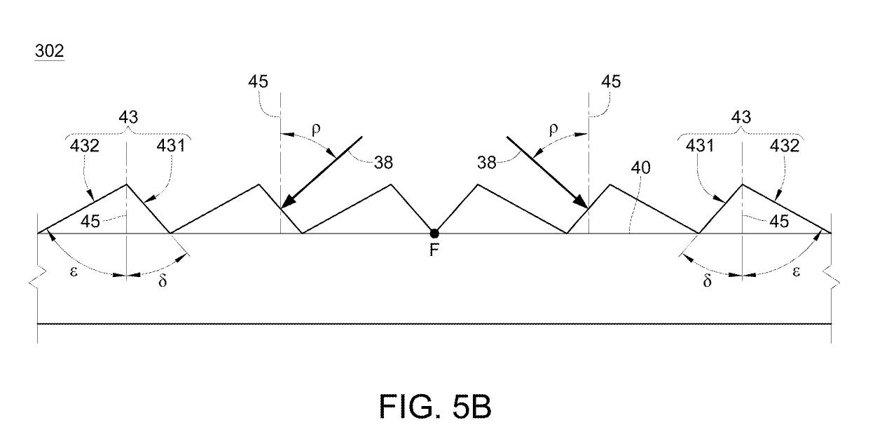

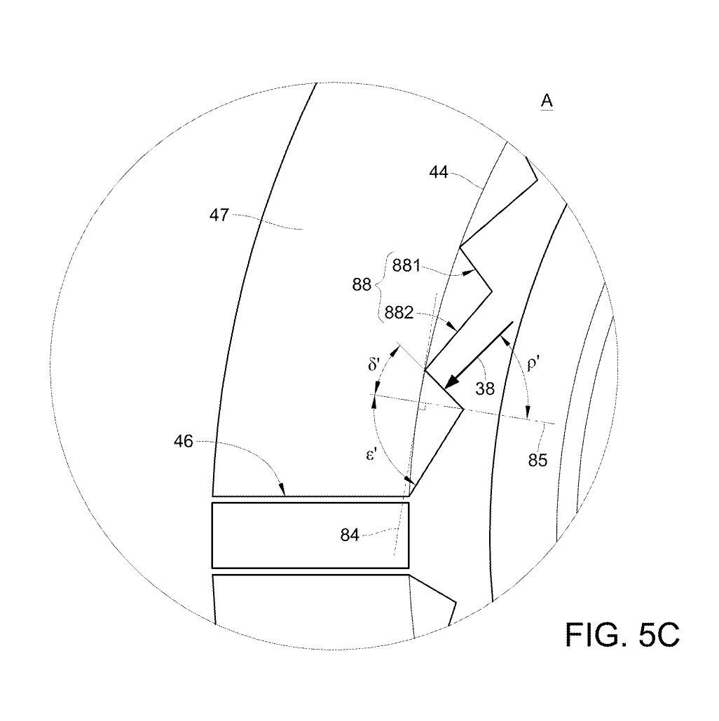

Please refer to FIG. 5A and FIG. 5B. FIG. 5A is a top view of a light concentration module according to a third embodiment of the disclosure. FIG. 5B is a sectional view of a primary light concentration plate in FIG. 5A according to an embodiment of the disclosure. In this embodiment, the light concentration module 300 comprises a primary light concentration plate 302, two light concentration components 304 and two electricity generation modules 306.

The primary light concentration plate 302 is in a round shape and comprises a primary light concentration surface 40 and a light-emitting surface 42. Each of the light concentration component 304 comprise a first surface 44 and two second surfaces 46. The area of the first surface 44 is larger than that of the second surface 46. The two light concentration components 304 respectively comprise a light concentration element 47. In this embodiment, the light concentration element 47 is in an arch form, so as to surround the primary light concentration plate 302 which is in a round shape. In this embodiment, the two light concentration components 304 correspond to the two electricity generation modules 306 respectively.

The primary light concentration surface 40 is configured for collecting light 38 from a variety of incident directions, so as to cause the light 38 to be transmitted in the primary light concentration plate 302. The light-emitting surface 42 is configured for emitting light 38 collected by the primary light concentration surface 40. In the same light concentration component 304, the first surface 44 is configured for collecting a part of the light 38 from the light-emitting surface 42, and for emitting light 38 to the corresponding electricity generation module 306 via the two second surfaces 46. Thereby, the corresponding electricity generation module 306 is configured for converting light 38 from the second surfaces 46 to electricity. Specifically, two lateral surfaces (namely, the surfaces adjacent to the second surfaces 46) of each of the electricity generation modules 306 are configured for collecting light 38.

FIG. 5B is a sectional view, along an I-I′ line, of a primary light concentration plate in FIG. 5A according to an embodiment of the disclosure. In this embodiment, the primary light concentration surface 40 comprises a plurality of sixth microprism structures 43. The sixth microprism structures 43 are in a radial arrangement with a center point F (as shown in FIG. 5B). Each of the sixth microprism structures 43 comprises a sixth light-facing surface 431 and a sixth backlight surface 432. Each of the sixth microprism structures 43 satisfies the following conditions:

0°≦δ≦40°; and

45°≦ε<90°;

wherein δ is a sixteen included angle formed by the sixth light-facing surface 431 and a normal vector 45 of the primary light concentration surface 40, and ε is a seventeenth included angle formed by the sixth backlight surface 432 and the normal vector 45. Light 38 collected by the primary light concentration surface 40 and the normal vector 45 form a eighteenth included angle ρ. The eighteenth included angle ρ may be greater than or equal to 45 degrees and less than 90 degrees (namely 45°≦ρ<90°).

Please refer to FIG. 5A and FIG. 5C. FIG. 5C is a partial enlarged view of the region A in FIG. 5A. Each of the light concentration components 304 comprises a light concentration element 47 which is in an arch shape. Each of the light concentration elements 47 has a first surface 44 and a second surface 46. Each of the first surfaces 44 may comprise a plurality of seventh microprism structures 88. Each of the seventh microprism structures 88 comprises a seventh light-facing surface 881 and a seventh backlight surface 882. Each of the seventh microprism structures 88 is arranged along a direction perpendicular to a vertical line 85 of a tangent line 84 of the of the first surface 44, wherein the tangent line 84 is perpendicular to the first surface 44. Each of the seventh microprism structures 88 satisfies the following conditions:

0°≦δ′≦40°; and

45°≦ε′<90°;

wherein δ′ is a nineteenth included angle formed by the seventh light-facing surface 881 and the vertical line 85, and ε′ is a twentieth included angle formed by the seventh backlight surface 882 and the vertical line 85. Light 38 collected by the light concentration element 47 and the vertical line 85 form a twenty-first included angle ρ′. The twenty-first included angle ρ′ may be greater than or equal to 45 degrees and less than 90 degrees (namely 45°≦ρ′<90°).

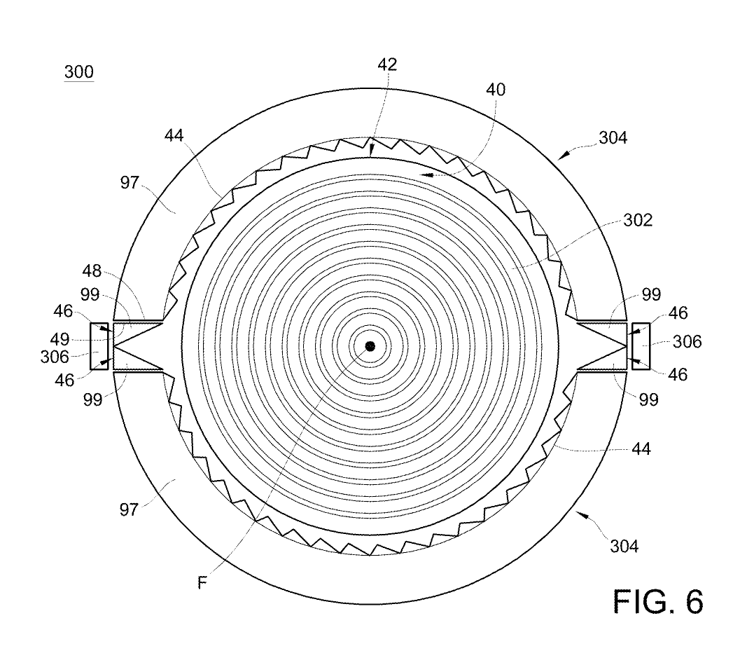

In the above-mentioned embodiment, two lateral surfaces of each of the electricity generation modules are configured for collecting light 38 from the second surface 46, but the disclosure is not limited thereto. To illustrate this point, please refer to FIG. 6, which is a top view of a light concentration module according to a fourth embodiment of the disclosure. In this embodiment, each of the light concentration components 304 comprises a first light concentration element 97 and two second light concentration elements 99.

The first light concentration element 97 is in an arch shape. The second light concentration element 99 is wedge-shaped. Each of the first light concentration elements 97 comprises a first surface 44 and a third surface 48. Each of the second light concentration elements 99 comprises a second surface 46 and a fourth surface 49. The first light concentration element 97 is disposed adjacent to the second light concentration element 99. Specifically, the fourth surface 49 of the second light concentration element 99 is disposed oppositely to the third surface 48 of the first light concentration element 97.

Light 38 collected by the light concentration component 304 is transmitted in the first light concentration element 97 after being collected by the first surface 44 of the first light concentration element 97. Then, light 38 is emitted from the first light concentration element 97 by the third surface 48, followed by being collected by the fourth surface 49 of the second light concentration element 99. Subsequently, light 38 is transmitted in the light concentration element 99 and is emitted by the second surface 46. The second light concentration element 99 is configured for collecting light 38 and changing its direction. Thereby, in this embodiment, each of the electricity generation modules 306 may be an electricity generation module utilizing a single surface to collect the light 38.

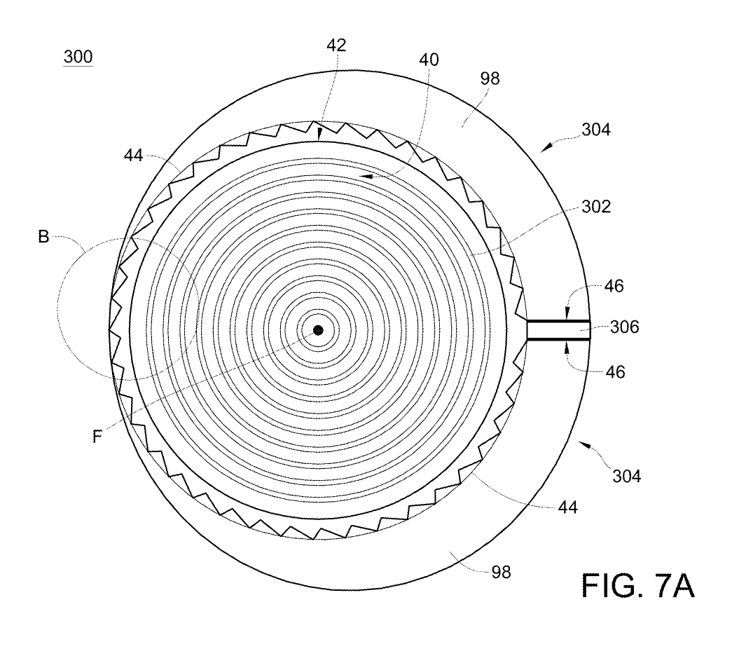

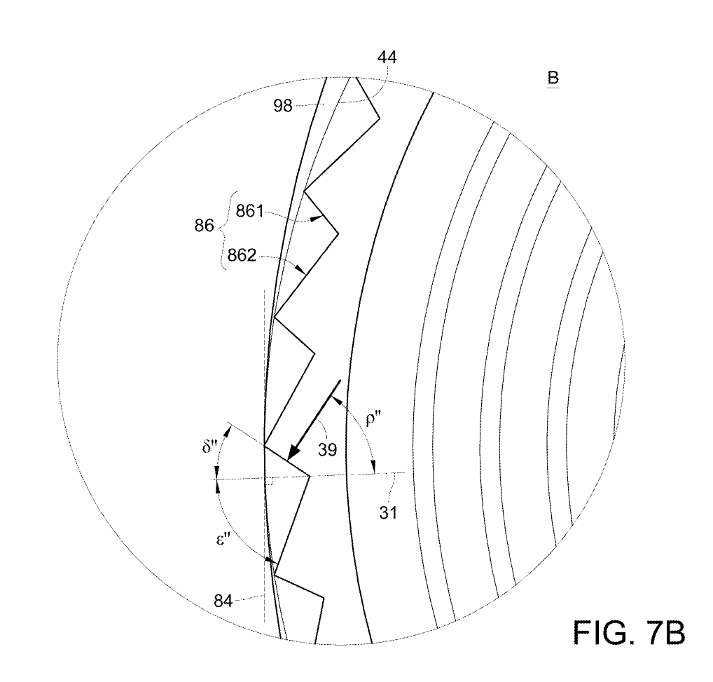

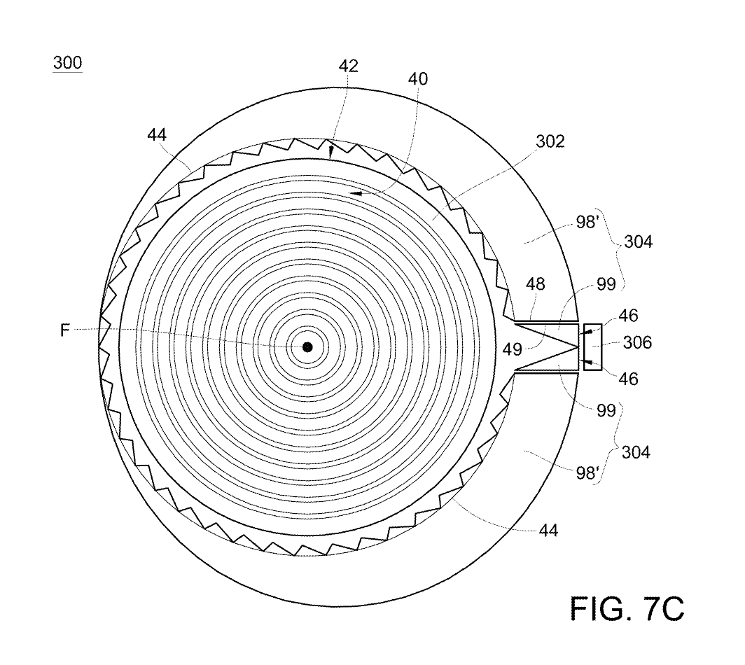

In the above-mentioned third and fourth embodiments, each of the light concentration components comprises two second surfaces 46, and the quantity of the electricity generation module 306 is two, but the disclosure is not limited thereto. For example, please refer to FIG. 7A, which is a top view of a light concentration module according to a fifth embodiment of the disclosure. In this embodiment, each of the light concentration components 304 comprises a light concentration element 98.

The light concentration element 98 is wedge-shaped and curved. Each of the light concentration elements 98 has a first surface 44 and a single second surface 46. The quantity of the electricity generation module is 1 and the electricity generation module is configured for utilizing two surfaces to collect light 38. Moreover, please refer to FIG. 7A and FIG. 7B. FIG. 7B is a partial enlarged view of the region B in FIG. 7A. The light concentration element 98 further comprises a plurality of eighth microprism structures 86. Each of the eighth microprism structures 86 comprises an eighth light-facing surface 861 and an eighth backlight surface 862. Each of the eighth microprism structures 86 is arranged along a direction perpendicular to a vertical line 31 of the tangent line 84 of the first surface 44, wherein the tangent line 84 is perpendicular to the first surface 44. Each of the eighth microprism structures 86 satisfies the following conditions:

0°≦δ″≦40°; and

45°≦δ″<90°;

wherein δ″ is a twenty-second included angle formed by the eighth light-facing surface 861 and the vertical line 31, and ε′ is a twenty-third included angle formed by the eighth backlight surface 862 and the vertical line 31. Light 39 collected by the light concentration element 98 and the vertical line 31 form a twenty-fourth included angle ρ″ and the twenty-fourth included angle ρ″ may be greater than or equal to 45 degrees and less than 90 degrees (namely) 45°≦ρ′<90°).

Furthermore, please refer to FIG. 7C, which is a top view of a light concentration module according to a sixth embodiment of the disclosure. In this embodiment, the quantity of the electricity module is 1. Each of the light concentration components 304 comprises a first light concentration element 98′ and two second light concentration elements 99. The first light concentration element 98′ is wedge-shaped and curved. The second light concentration element 99 is wedge-shaped.

Each of the first light concentration elements 98′ comprises a first surface 44 and a third surface 48. Each of the second light concentration elements 99 comprises a second surface 46 and a fourth surface 49. The first light concentration element 98′ is disposed next to the second light concentration element 99. Specifically, the fourth surface 49 of the second light concentration element 99 is disposed oppositely to the third surface 48 of the first light concentration element 98′.

After collecting by the first surface 44 of the first light concentration element 98′, light 39 collected by the light concentration component 304 is transmitted in the first light concentration element 98′. Light 39, subsequently, is emitted from the first light concentration element 98′ by the third surface 48. Then, light 39 is collected by the fourth surface 49 of the second light concentration element 99 and is transmitted in the second light concentration element 99, followed by being emitted from the second surface 46. The second light concentration element 99 is configured for collecting light 39 collected by the first light concentration element 98′ and for changing its direction. Thereby, in this embodiment, the electricity generation module 306 may be an electricity generation module utilizing a single surface to collect light 39.

According to the embodiments of the light concentration module disclosed, the area of the first surface is larger than that of the second surface so that the concentration ratio of the light concentration module is increased. Thereby the area required for the photoelectric electricity generation module is reduced and this leads to a reduction of the manufacturing cost thereof. Additionally, the primary light concentration plate can collect light from a variety of directions due to the design of multiple subsidiary light concentration surfaces, and thereby convert light to electricity by the photoelectric electricity generation module. The primary light concentration plate can collect light from any direction because of the microprism structures of the subsidiary light concentration surfaces, wherein the microprism structures are in a radial arrangement. Consequently, the light concentration module of the disclosure can address the problem of the complex design, and sensors being prone to be interfered and damaged resulting in detecting errors. Furthermore, the light concentration module of the disclosure can solve the problem that the light concentration module in the related art can only collect light from a single direction of incidence.

What is claimed is:

1. A light concentration module, comprising:
a primary light concentration plate comprising a primary light concentration surface and a light-emitting surface, the primary light concentration surface being configured for collecting light, the light-emitting surface being configured for emitting light collected by the primary light concentration surface;
a light concentration component comprising a first surface and a second surface, the first surface collecting light from the light-emitting surface, the area of the first surface is larger than the area of the second surface; and
an electricity generation module, the second surface being configured for emitting light collected by the first surface, the electricity generation module being configured for converting energy from light into electricity.

2. The light concentration module according to claim 1, wherein the primary light concentration surface further comprises a plurality of first microprism structures, the first microprism structures are arranged along a first direction.

3. The light concentration module according to claim 2, wherein each of the first microprism structure comprises a first light-facing surface and a first backlight surface, the first direction is perpendicular to a normal vector of the primary light concentration surface in which the normal vector is perpendicular to the primary light concentration surface, and each of the first microprism structures satisfies the following conditions:
0°≦α≦40°; and
45°≦β<90°;
wherein α is a first included angle formed by the first light-facing surface and the normal vector, and β is a second included angle formed by the first backlight surface and the normal vector.

4. The light concentration module according to claim 1, wherein light collected by the primary light concentration surface and a normal vector perpendicular to the primary light concentration surface form a third included angle, the third included angle being greater than or equal to 45 degrees and less than 90 degrees.

5. The light concentration module according to claim 1, wherein the first surface comprises a plurality of second microprism structures and the second microprism structures are arranged along a second direction.

6. The light concentration module according to claim 5, wherein the light concentration component further comprises a light concentration element, the light concentration element has the first surface and the second surface, each of the second microprism structures comprises a second light-facing surface and a second backlight surface, the second direction is perpendicular to a vertical line which is perpendicular to the first surface, and each of the second microprism structures satisfies the following conditions:
0°≦α′≦40°; and
45°≦β′<90°;
wherein α′ is a fourth included angle formed by the second light-facing surface and the vertical line, and β′ is fifth included angle formed by the second backlight surface and the vertical line.

7. The light concentration module according to claim 6, wherein light collected by the light concentration element and the vertical line form a sixth included angle, and the sixth included angle is greater than or equal to 45 degrees and less than 90 degrees.

8. The light concentration module according to claim 1, wherein the primary light concentration surface comprises a plurality of subsidiary light concentration surfaces, the subsidiary light concentration surfaces intersect at a center point, the light concentration module further comprises a plurality of the light concentration components and a plurality of the electricity generation modules, the primary light concentration plate further comprises a plurality of the light-emitting surfaces, the subsidiary light concentration surfaces correspond to the light-emitting surfaces respectively, the light-emitting surfaces correspond to the light concentration components respectively, the light concentration components correspond to the electricity generation modules respectively, the light concentration surfaces are configured for collecting light from a variety of incident directions and for transmitting light to the corresponding light-emitting surfaces, each of the light-emitting surfaces are configured for emitting light collected by each of the subsidiary light concentration surfaces to the corresponding light concentration component, each of the light concentration components is configured for emitting light to the corresponding electricity generation module via the second surface.

9. The light concentration module according to claim 8, wherein light collected by each of the subsidiary light concentration surfaces and a normal vector of the primary light concentration surface form a seventh included angle wherein the normal vector of the primary light concentration surface is perpendicular to the primary light concentration surface, and the seventh included angle is greater than or equal to 45 degrees and less than 90 degrees.

10. The light concentration module according to claim 8, wherein each of the subsidiary surfaces comprises a plurality of third microprism structures, the third microprism structures are arranged along a corresponding direction, and the corresponding direction is from the center point to the light-emitting surface corresponding to each of the subsidiary light concentration surfaces.

11. The light concentration module according to claim 10, wherein each of the third microprism structures comprises a third light-facing surface and a third backlight surface, the corresponding direction is perpendicular to a normal vector of the primary light concentration surface wherein the normal vector is perpendicular to the primary light concentration surface, and each of the third microprism structures satisfies the following conditions:
0°≦α″≦40°; and
45°≦β″<90°;
wherein α″ is an eighth included angle formed by the third light-facing surface and the normal vector, and β″ is a ninth included angle formed by the third backlight surface and the normal vector.

12. The light concentration module according to claim 1, wherein the light concentration component comprises a first light concentration element and a second light concentration element, the first light concentration element comprises the first surface and a third surface, the second light concentration element comprises the second surface and a fourth surface, light collected by the light concentration component is configured for being transmitted in the first light concentration element after light is collected by the first surface of the first light concentration element, light is then emitted from the third surface and is collected by the fourth surface of the second light concentration element, and light is subsequently transmitted in the second light concentration element and is emitted from the second surface.

13. The light concentration module according to claim 12, wherein the fourth surface of the second light concentration element and the third surface of the first light concentration element are disposed oppositely to each other.

14. The light concentration module according to claim 12, wherein the area of the first surface is larger than the area of the third surface, and the area of the fourth surface is larger than the area of the second surface.

15. The light concentration module according to claim 12, wherein the first surface comprises a plurality of fourth microprism structures, each of the fourth microprism structures comprises a fourth light-facing surface and a fourth backlight surface, the fourth microprism structures are arranged along a direction perpendicular to a vertical line of the first surface, and each of the fourth microprism structures satisfies the following conditions:
0°≦χ≦40°; and
45°≦ω<90°;
wherein χ is a tenth included angle formed by the fourth light-facing surface and the vertical line, and ω is an eleventh included angle formed by the fourth backlight surface and the vertical line.

16. The light concentration module according to claim 15, wherein light collected by the first light concentration element and the vertical line form a twelfth included angle, the twelfth included angle is greater than or equal to 45 degrees and less than 90 degrees.

17. The light concentration module according to claim 12, wherein the fourth surface further comprises a plurality of fifth microprism structures, each of the fifth microprism structures comprises a fifth light-facing surface and a fifth backlight surface, the fifth microprism structures are arranged along a direction perpendicular to a vertical line of the fourth surface wherein the vertical line is perpendicular to the fourth surface, and each of the fifth microprism structures satisfies the following conditions:
0°≦χ′≦40°; and
45°≦ω′<90°;
wherein χ′ is a thirteenth included angle formed by the fifth light-facing surface and the vertical line, and ω′ is a fourteenth included angle formed by the fifth backlight surface and the vertical line.

18. The light concentration module according to claim 17, wherein light collected by the second light concentration element and the vertical line form a fifteenth included angle, and the fifteenth included angle is greater than or equal to 45 degrees and less than 90 degrees.

19. The light concentration module according to claim 1, wherein the primary light concentration plate is in a round shape, the primary light concentration surface comprises a plurality of sixth microprism structures, and the sixth microprism structures are in a radial arrangement with a center point and the center point is a circle center of the primary light concentration plate.

20. The light concentration module according to claim 19, wherein each of the sixth microprism structures comprises a sixth light-facing surface and a sixth backlight surface, and each of the sixth microprism structures satisfies the following conditions:
0°≦δ≦40°; and
45°≦ε<90°;
wherein δ is a sixteen included angle formed by the sixth light-facing surface and the normal vector of the primary light concentration surface, and ε is a seventeenth included angle formed by the sixth backlight surface and the normal vector.

21. The light concentration module according to claim 19, wherein the light concentration component comprises a light concentration element, the light concentration element is in an arch form and has the first surface and the second surface, the first surface comprises a plurality of seventh microprism structures, each of the seventh microprism structures comprises a seventh light-facing surface and a seventh backlight surface, each of the seventh microprism structures is arranged in a direction perpendicular to a vertical line of a tangent line of the first surface, and each of the seventh microprism structures satisfies the following conditions:
0°≦δ′≦40°; and
45°≦ε′<90°;
wherein δ′ is a nineteenth included angle formed by the seventh light-facing surface and the vertical line, and ε′ is a twentieth included angle formed by the seventh backlight surface and the vertical line.
